(19) United States
(12) Patent Application Publication
(10) Pub. No.: US 2019/0330054 A1
(43) Pub. Date: Oct. 31, 2019

(54) COATED OPTICAL ELEMENT COMPONENT WITH A COATED OPTICAL ELEMENT AND METHOD TO PRODUCE THE SAME

(71) Applicant: Schott AG, Mainz (DE)

(72) Inventors: Marcelo David Ackermann, Neuchatel (CH); Michael Gunnar Garnier, La Chaux-de-Fonds (CH); Dirk Apitz, Lausanne (CH); Ulf Georg Brauneck, Gross-Umstadt (DE)

(73) Assignee: Schott AG, Mainz (DE)

(21) Appl. No.: 16/394,722

(22) Filed: Apr. 25, 2019

(30) Foreign Application Priority Data
Apr. 27, 2018 (DE) 10 2018 110 193.7

(51) Int. Cl. B81B 7/00; G02B 1/10; B81C 1/00

(52) U.S. Cl. CPC B81B 7/0067; G02B 1/10; B81C 2203/031; B81C 2203/0118; B81C 1/00317

(57) ABSTRACT

An optical element includes an optically transparent substrate of alkali containing glass and a coating on a surface, the coating enabling anodic bonding of the alkali containing glass within an area of the surface that is covered with the coating and with the anodic bond forming at the outer surface of the coating.

### BACKGROUND OF THE INVENTION

### 1. Field of the Invention

The invention generally relates to thin-film coated optical elements such as elements with an antireflective coating, or coated with a dielectric wavelength filter, or a partially reflective or absorptive coating. In particular, the invention relates to arrangements where the optical element is fixed to a further element by anodic bonding at the interface where the coating is applied.

### 2. Description of the Related Art

U.S. Patent Application Publication No. 2003/0021004 A1 discloses a method for producing an optical MEMS device, wherein an optically transmissive substrate is provided, an optical coating is deposited on one or both surfaces of the substrate to enable or improve the transmission of an optical signal along a path directed through the optical coating and the substrate. The substrate typically encloses an active or passive optical element, which can be an optical sensor, optical emitter or a passive movable, actuatable microstructure, whereby actuation of the microstructure causes the microstructure to interact with the optical signal. The optical coating applied to such substrates is patterned such that it exists only under/above the active or passive or actuatable portion of microstructure, i.e., in the path of the optical signal, and not at the areas on the first substrate where bonding to second substrate is effected.

Anodic bonding is a standard method in the fabrication of MEMS-devices, particularly for packaging the device. Alkali-containing glasses are used for the bonding. Suitable are soda containing borosilicate glasses or soda-lime glasses. To effect the anodic bonding, the glass is heated until the alkali-ions become mobile within the glass. An electrical field is applied so that the alkali ions move towards the electrode contacting the glass. This results in a charge depletion zone at the interface, which exerts electrostatic forces pressing the substrates together. The close contact of the substrate surfaces results in formation of physical and chemical bonds between the substrates.

Structuring the coating as it is also disclosed in U.S. Patent Application Publication No. 2003/0021004 A1 may, e.g., be accomplished by selective etching, lithographic patterning and lift-off or physical masking. This, however, is costly and requires additional process steps, e.g. in the production of MEMS devices. Moreover, the structuring may harm or degrade the coating.

What is needed in the art is a way to facilitate and improve fabrication of components or modules with coated optical elements.

### SUMMARY OF THE INVENTION

According to exemplary embodiments provided in accordance with the invention, an optical element comprising an optically transparent substrate of alkali containing glass and a coating on a surface is provided. This specific coating is not prohibitive to and enables anodic bonding of the alkali containing glass within the area of the surface that is covered with the coating and with the anodic bond forming, or being established, respectively, at the outer surface of the coating.

It has so far been assumed that anodic bonding requires a direct interface between the glass and the substrate. In the case of coated glass, it was assumed that the presence of the coating between the glass and substrate is prohibitive for bonding. It was assumed that a patterning step is necessary to keep the bonding area free of coating, to have direct glass-Si or glass-metal contact. This requires masking steps prior to coating or selective/local etching steps after coating. This is an additional and costly process step. It also requires the correct alignment of the pattern where the bare glass is exposed to the substrate. Especially in the case of small parts (MEMS), this alignment requires advanced and expensive process equipment. However, surprisingly, there are coatings which are compatible with the bonding process. Thus, according to an exemplary embodiment, the coating has one or more of the following features:

the material of the coating is not capable of being anodically bonded,

the coating itself does not contain alkali ions in sufficient amount to establish a charge depletion zone at the interface of the anodic bond, and/or

the alkali content in mol % is less than 1/10th of the alkali content of the alkali containing glass.

To obtain a reliable bond to the coating, the outer surface of the coating may be hydrophilic or polar. This facilitates formation of chemical bonds between the surface of the coating and the further element to be connected to the optical element.

In some exemplary embodiments, an optically functional module or component is provided, the component comprising an optical element having an optically transparent substrate of alkali containing glass and a coating on a surface of the substrate, and a second substrate connected to the optically transparent substrate. The second substrate is connected to the optically transparent substrate by an anodic bond at an area of the surface covered with the coating so that the coating is arranged between the optically transparent substrate and the second substrate and is in direct contact with both the optically transparent substrate and the second substrate.

The connection of the substrate by the anodic bond in this configuration is established at the interface between the coating and the surface of the second substrate. This way, the coating does not need to be removed in the contact area.

The coating may consist of a single layer or may contain a sequence of at least two layers.

In some embodiments, the substrate has a face, in particular a plane face that is fully covered by the coating. The substrate may be disc shaped having two opposed plane faces or sides, respectively. In this configuration, at least one of the faces may be fully covered with the coating as explained above. However, a circumferential coating exclusion zone on the face can be provided.

In some embodiments, the second substrate is a silicon substrate such as a silicon wafer or a metal substrate. Silicon substrates anodically bonded to glass substrates may be employed to fabricate MEMS components. Thus, in some embodiments, the optical component is a MEMS-device, such as a MOEMS device. The other substrate to be bonded to the optical element does not need to be entirely made of silicon or metal. However, the section bonded to the optical element may be a silicon or metal part. Thus, more generally, the second substrate comprises a silicon or metal part that is bonded to the optical element. The silicon may be covered with silicon oxide, in particular covered with a native oxide layer. In this case, the silicon oxide forms the surface of the part that bonds to the optical element.

In some embodiments, the second substrate may be provided with a coating on the side that is bonded to the glass substrate. Such a coating may, e.g., be a metallic or oxidic coating. For example, the side to be bonded to the glass substrate may be provided with an aluminium coating or an SiO₂-coating.

Suitable materials for the topmost layer or, generally, for the outer surface of the coating are

SiO₂, SiOₓ (i.e. generally silicon oxide), Al₂O₃AlOₓ (i.e. generally aluminium oxide),

metal,

metal oxides like Sc₂O₃, Ta₂O₅, Nb₂O₅, ZrO₂, TiO₂ and HfO₂,

fluorides and sulfides like MgF₂, ZnS, Bariumfluoride (BaF₂), Calciumfluoride (CaF₂), Ceriumfluoride (CeF₃), Lanthanfluoride (LaF₃), Neodymfluoride (NdF₃), Ytterbiumfluoride (YbF₃), Aluminiumfluoride (AlF₃), Dysprosiumfluoride (DyF₃), and Yttriumfluoride (YF₃),

mixtures thereof, i.e. materials which contain one or more of the mentioned materials listed above (thus also doped and mixed materials containing at least one of these mentioned materials), e.g. Al-doped SiO₂, or Si-doped TiO₂.

The coating or at least its topmost layer, or its outer surface may be inorganic to allow for an anodic bond.

In some embodiments, the coating comprises at least two layers. With multilayer coatings, more complex optical functions may be realized, such as multilayer antireflective or dichroic filters.

The coating may also comprise a layer of a material that itself cannot be bonded at its surface by anodic bonding. In this case, this layer is covered with a layer of bondable material, e.g. a SiO₂- or Al₂O₃-layer. This topmost layer does not necessarily need to have an optical function but functions to establish chemical bonds to the other substrate. Accordingly, in some embodiments the coating comprises at least two layers.

In some embodiments, the coating comprises a layer of a non-bonding material that does not bond to other surfaces by anodic bonding. The coating comprises a further layer of a material that enables anodic bonding of the alkali containing glass on the area of the surface that is covered with the coating, i.e. which establishes physical or chemical bonds to another substrate under influence of the charge depletion zone.

To produce the component, a method for fabricating a component with an optical element is also provided according to the present invention. The method includes:

providing an optically transparent substrate of an alkali containing glass,

depositing a coating on a surface of the substrate, the coating enabling anodic bonding of the alkali containing glass on the area of the surface that is covered with the coating,

bringing a second substrate into contact with the coating on the optically transparent substrate,

heating the optically transparent substrate up to a temperature that enables diffusion of alkali ions in the glass, and

applying a voltage across the stack of the optically transparent substrate and the second substrate so that alkali ions migrate within the bulk of the glass creating an alkali depletion zone and the optically transparent substrate with coating under the influence of the electrostatic field generated by the applied voltage and ion depletion zone at the interface and the second substrate are bonded together.

The anodic bond may be characterized by a lasting depletion zone in the glass at the interface to the coating in which the alkali content is reduced with respect to the bulk of the glass or the opposite face of the substrate. Thus, in some embodiments, the glass of the substrate of the optical element has an alkali depletion zone at the interface to the coating, although the depletion may level out over time.

As in a conventional fabrication, an anodic bond is established. In contrast, however, the alkali-depletion occurs not directly at the bonded surfaces but rather at the interface from the glass to the coating.

In some embodiments,

the stack of substrate and coated glass is heated to a temperature above 250° C. but below the glass transition temperature (Tg) of the glass, and

the voltage applied to generate the electric field is above 250V, and

a bond strength is achieved surpassing the fracture strength of the glass of the transparent substrate. To avoid voltage breakdown and eventual damage of the device, the applied voltage may be limited to less than 1500 V.

In some embodiments, the component has a bond strength of the anodic bond between the coating and the second substrate that exceeds 7 MPa, such as at least 10 MPa.

### BRIEF DESCRIPTION OF THE DRAWINGS

The above-mentioned and other features and advantages of this invention, and the manner of attaining them, will become more apparent and the invention will be better understood by reference to the following description of embodiments of the invention taken in conjunction with the accompanying drawings, wherein:

FIG. 1 illustrates a cross sectional view of an exemplary embodiment of an optical element with a coating provided according to the invention.

FIG. 2 illustrates a cross sectional view of an exemplary embodiment of an optical element with a multilayer coating provided according to the invention.

FIG. 3 illustrates a variant of the optical element of FIG. 1 with an added thin layer.

FIG. 4 illustrates a variant of the optical element of FIG. 1 with a multilayer of non-bonding materials.

FIG. 5 illustrates a variant of the optical element of FIG. 1 with a multilayer of alternating bonding and non-bonding materials.

FIG. 6 is a variant of the embodiment of FIG. 4 with a coating on both faces of the substrate.

FIG. 7A illustrates an exemplary embodiment of a wafer processed in accordance with the invention.

FIG. 7B illustrates a wafer provided in accordance with a known process.

FIG. 8A illustrates an exemplary embodiment of a component with a coated optical element provided according to the present invention.

FIG. 8B illustrates a comparative example wafer that is conventionally produced.

FIG. 9 illustrates a wafer package with a transparent wafer bonded to a device wafer.

Corresponding reference characters indicate corresponding parts throughout the several views. The exemplifications set out herein illustrate embodiments of the invention and such exemplifications are not to be construed as limiting the scope of the invention in any manner.

### DETAILED DESCRIPTION OF THE INVENTION

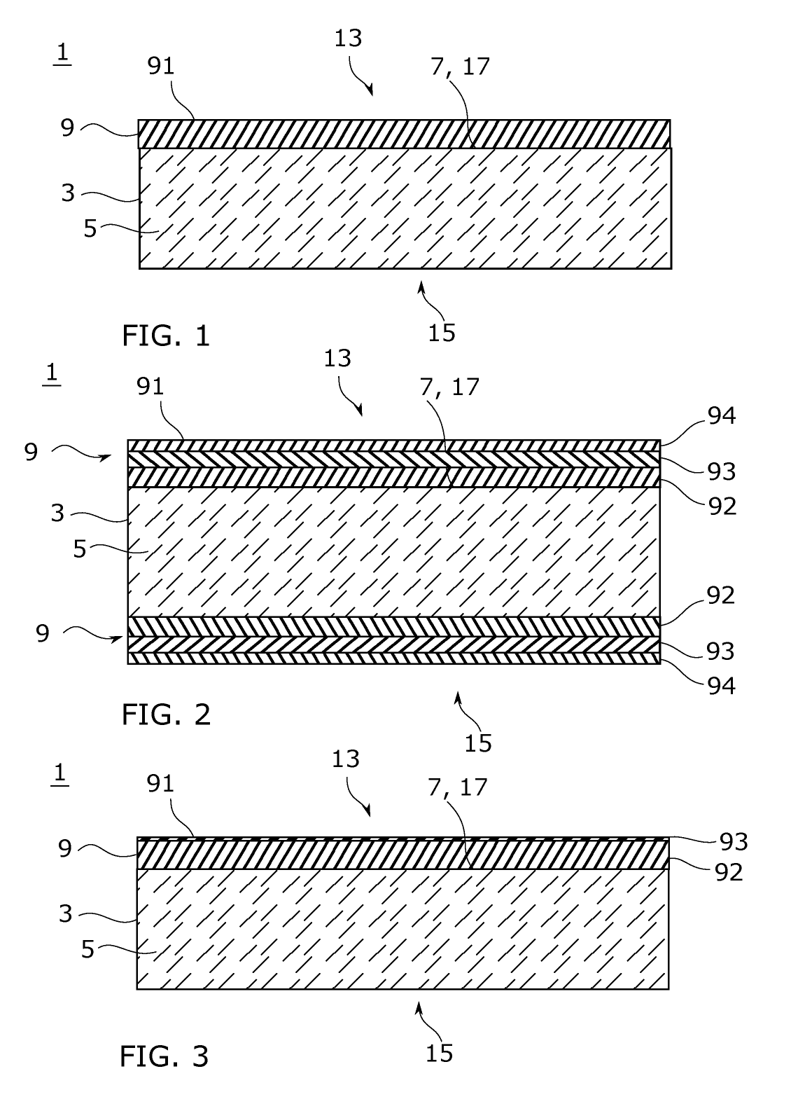

FIG. 1 shows an exemplary embodiment of an optical element 1 provided according to the invention. The optical element 1 comprises an optically transparent substrate 3 of alkali containing glass 5 and a coating 9 on a surface 7 of the substrate 3. The glass of the substrate is of a type that allows for anodic bonding. Accordingly, the alkali ions of the glass are movable within the glass matrix at elevated temperatures below the softening point. With the coating 9 an anodic bonding of the alkali containing glass 5 is possible within the area of the surface 7 that is covered with the coating 9 and with the anodic bond forming at the outer surface 91 of the coating. In some embodiments, the substrate 3 comprises two opposed faces 13, 15, where one of the faces 13 forms the surface 7 onto which the coating 9 is deposited.

Surprisingly and without restriction to the specific embodiment of FIG. 1, the coating 9 itself does not need to be of a material which is capable of being anodically bonded. Specifically, the coating itself does not need to contain alkali ions in sufficient amount to establish a charge depletion zone at the interface of the bond, i.e. at the outer surface 91 of the coating. However, alkali depletion at the interface 17 still occurs in the glass due to the applied voltage so that a strong electrostatic field builds up between the substrates to be connected. The overall thickness of the coating may be in the range of from 2 nm to 50 μm, such as from 20 nm to 20 μm. Although the field strength drops with increasing layer thickness, the upper limit of 50 μm may still allow for stable and rigid bonds. Assuming that no considerable ion migration takes place inside the coating, the force of the electrical field will be too low to initiate bonding or at least to establish a bonding force of satisfactory strength. The relation between the thickness of the coating and the field strength is assumed to be roughly inversely linear, i.e. doubling the thickness of the coating will halve the electrostatic force. The coating thickness that is prohibitive for bonding will depend both on the maximum voltage that can be applied and the affinity of the surface for achieving the bond. This affinity may depend, e.g. on the density of OH⁻-groups at the surface in case of hydrophilic materials, the density of defects and inclusions. Thus, there is no definite limit on the thickness.

As shown, the plane face 13 of the substrate 3 is fully covered by the coating 9. The optical element can be used for the anodic bonding without further structuring of the coating. In some embodiments, without restriction to the specific exemplary embodiment of FIG. 1, the optical element is a glass wafer with one of its faces fully covered with the coating. In the deposition process there may be small areas at the wafer edge that are covered, e.g. due to clamps holding the wafer. This may result in small areas at the wafer edge without coating. As well, a circumferential coating exclusion zone can be provided for handling reasons. A wafer with a continuous coating but only small areas left open at the edge or a circumferential coating exclusion zone at the edge is still regarded as a wafer with a fully covered face.

To facilitate the bonding, the topmost layer material may be hydrophilic or polar. Generally, a hydrophilic or polar material is regarded as a material having a water contact angle of less than 45°, such as less than 25°. The contact angle at the surface may be larger due to contamination. However, this is not too critical as long as the layer forming material at the surface is hydrophilic. Thus, the contact angle as specified above may also be achieved after cleaning the surface.

Coating materials that, when applied as last layer of an optical coating 9 make the full coated wafer anodically bondable are potentially all materials which show hydrophilic bonding to the native oxide of Si and metals like Kovar.

This includes: SiO₂, SiOₓ, AI₂O₃, AlOₓ and metal layers. Further, metal oxides like Sc₂O₃, Ta₂O₅, Nb₂O₅, ZrO₂, TiO₂ and HfO₂ are suitable. Further, fluorides and sulfides like MgF₂, ZnS, Bariumfluoride (BaF₂), Calciumfluoride (CaF₂), Ceriumfluoride (CeF₃), Lanthanfluoride (LaF₃), Neodymfluoride (NdF₃), Ytterbiumfluoride (YbF₃), Magnesiumfluoride (MgF₂), Aluminiumfluoride (AIF₃), Dysprosiumfluoride (DyF₃), and Yttriumfluoride (YF₃) can be used, e.g. to utilize special optical characteristics like a low refractive index as it is the case with MgF₂.

The coating may also contain doped and mixed materials containing at least one of the above-mentioned compounds, e.g. Al-doped SiO₂, or Si-doped TiO₂.

FIG. 2 shows another exemplary embodiment that is similar to the embodiment of FIG. 1. In the embodiment illustrated in FIG. 2, the coating 9 comprises at least two layers. In the exemplary embodiment of FIG. 2, the coating comprises three layers 92, 93, 94. Further, as shown, a coating 9 may be applied to both opposing faces 13, 15 of the substrate. Generally, without restriction to the exemplary embodiments of FIG. 1 and FIG. 2, the coating 9 with one or more layers may in particular be one of

an anti-reflection coating,

a mirror coating (metallic, dielectric or combined) with or without protection layer(s),

a filter coating, such as a dichroic, polarizing, band-pass, low-pass, high-pass, neutral density, single or multiple notch filter or beam splitter coating, potentially offering dichroic or polarizing properties.

Further, the coating may include materials or layers that impart hardness and/or scratch resistance. Coating materials of this type may be nitrides, oxynitrides, carbonitrides or carbides, such as silicon carbide, aluminium nitride, titanium nitride or silicon nitride or mixed materials.

In addition, materials or layer designs with high LIDT, low absorption, low reflective or diffractive losses may be employed.

The coating may also include non-bonding materials. For example, in the embodiment shown in FIG. 2, one or both of the layers 92, 93 may be from materials that are not itself suitable for anodic bonding. In this case, i.e., if the coating 9 comprises a layer of a non-bonding material that does not bond to other surfaces by anodic bonding, a further layer is provided. This further layer is of a material that enables anodic bonding of the alkali containing glass on the area of the surface that is covered with the coating. In the embodiment of FIG. 2, accordingly, the topmost layer 94 is of a material that bonds to other materials by anodic bonding. For example, the topmost layer 94 may be a SiO₂-, SiOₓ- or Al₂O₃-layer. The coating itself does not need to contain alkali ions in an amount sufficient to create a charge depletion zone that allows for an anodic bond. The alkali content of the coating, if any, may be less than one tenth of the alkali content of the glass measured in mol %.

The coating 9 may also substantially consist of one or more non-bonding materials. To employ such a coating, a thin layer of a bondable material which has no optical function (typically SiO₂ or AI₂O₃), but which is there solely to allow for anodic bonding, may be deposited on top of the non-bonding material. FIG. 3 shows an exemplary embodiment with a layer 92 of a non-bonding material. On this layer 92, a further, thin layer of a bonding material (such as the aforementioned SiO₂ or AI₂O₃) is deposited. As this layer 93 only serves to establish the chemical bonds to the other substrate, it may be very thin. According to some embodiments, the coating 9 comprises a layer 92 of a non-bonding material and a further layer 93 of a bonding material on top of the layer 92 of non-bonding material, the further layer forming the outer surface of the coating 9 and having a thickness of between 1 nm and 20 nm, such as between 4 nm and 20 nm or between 5 nm and 15 nm.

The overall thickness of the coating may be in the range of from 2 nm to 50 μm, such as from 20 nm to 20 μm.

In some embodiments, when the topmost layer of a multilayer stack also has a contribution to the optical function, the thickness of the layer is from 50 nm to 1000 nm. This is also an exemplary range of thickness of a single layer coating, when this coating has an optical function for the visible range of light (wavelength typically from 400 to 700 nm). For layers having optical properties in the NIR or IR range, the typical layer thickness increases linearly with the wavelength, leading to layers of, for example, 125 nm to 1000 nm thickness.

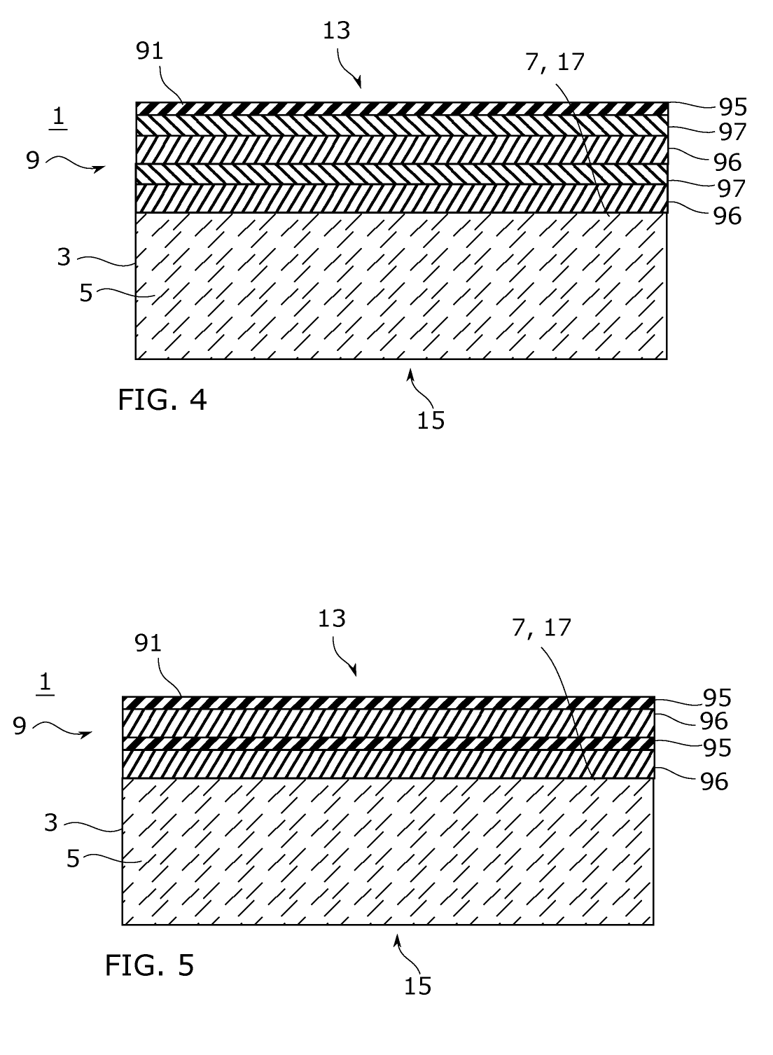

FIG. 4 shows an exemplary embodiment with a multilayer of non-bonding materials. According to this embodiment, the coating 9 is a multilayer stack of layers. The coating 9 may comprise a stack of alternating layers 96, 97. The material of both layer types 96, 97 are potentially non-bonding, i.e. not suitable for anodic bonding. In this embodiment, the stack is terminated with a layer 95 of a bonding material which consequently forms the outer surface 91 of the coating 9. The terminating layer may have an optical function. As well, the layer can be very thin as explained above, so that it does not contribute considerably to the optical properties of the coating 9.

In the exemplary embodiment of FIG. 5, the coating 9 comprises a multilayer stack of alternating layers 95, 96, where layers 95 are of a bondable material and layers 96 are of a non-bondable material. The sequence of alternating layers 95, 96 is terminated with a topmost layer 95 of a bondable material.

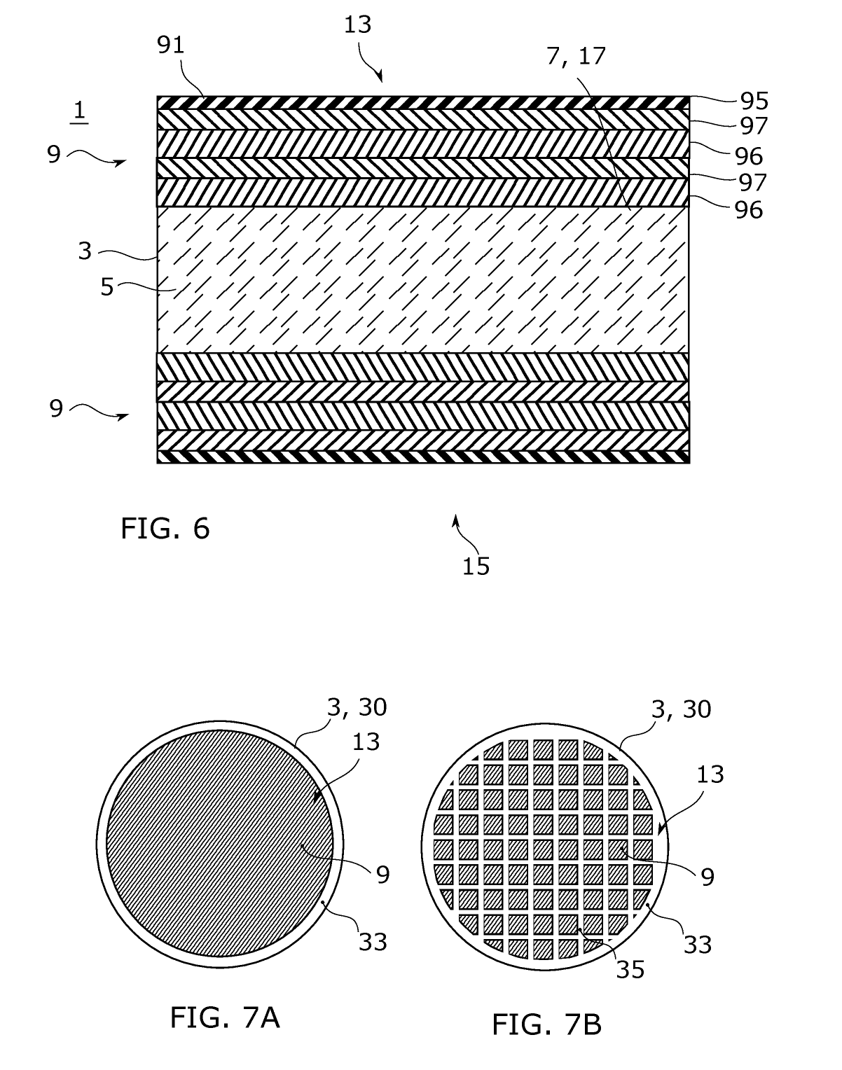

A multilayer coating 9 with an alternate layer system may be deposited on both faces of a substrate 3, as shown in the exemplary embodiment of FIG. 6. In the embodiment shown, both coatings are identical regarding their succession of layers and the termination by a layer 95 of a bonding material. The terminating layer 95 may also be omitted on the coating that is not bonded to another substrate.

Generally, without restriction to any of the depicted exemplary embodiments, the number of layers of the coating 9 can range from 1 to more than 300. Typically, e.g. for an antireflection functionality, it will be 1 to 8 layers. For complex filters (e.g. a notch filter), it can be even between 300 and 600 layers.

The deposition technique can be any thin film deposition method, including but not limited to PVD (physical vapour deposition), CVD (chemical vapour deposition) or ALD (atomic layer deposition), and specifically for PVD these could be but are not limited to e-beam evaporation, Ion Beam Sputtering, Magnetron Sputtering, Ion Assisted Deposition, thermal evaporation, or any other thin film coating technique. An example discussed further herein has been made using Ion Assisted Deposition.

The wavelength range in which the substrate is transparent may be from 250 nm up to 4 μm. Accordingly, the term “optically transparent” as used herein is not limited to the visible wavelength range but also includes infrared and ultraviolet light. More specifically, the visible range (400 to 700 nm), the near infrared (850 to 2500 nm) and the mid-infrared (2500 to 3500 nm), and especially the typical laser wavelength for telecommunication and laser ranging applications (905, 950, 1030, 1050, 1064, 1535, 1550 and 1570 nm) and the wavelengths for LED and OLED light sources (visible wavelength in red green and blue) and any wavelength generated e.g. by an OPO are relevant for an optical component provided according to the invention. Thus, it is contemplated that the substrate is transparent to at least one of these wavelengths or wavelength ranges.

The roughness (Rq) of the outer surface 91 may be between 0.1 and 2 nm RMS, but can be less than 0.1 nm RMS (no lower limit) or higher than 2 nm RMS. The roughness may be influenced by the deposition parameters, e.g. by the power density in a plasma deposition process. A low roughness generally is advantageous to facilitate the anodic bonding and to strengthen the bond.

FIGS. 7A and 7B illustrate two substrates 3. Both substrates 3 are wafers 30 which may be employed in a wafer level anodic bonding process after which components can be separated. The wafer in FIG. 7A is a wafer 30 that can be processed according to the invention. A face 13 of wafer 30 is fully covered with the coating 9 with a circumferential coating exclusion zone 33 left open. The wafer in FIG. 7B is a wafer 30 as it is used in a conventional process. The coating 9 does not fully cover the area inside the circumferential coating exclusion zone 33 but is further structured with stripe shaped bonding areas 35 left open. These areas are envisaged to anodically bond the wafer to a further substrate so that the further substrate has direct contact to the wafer material. However, this structuring requires further processing. Also, the alignment between the wafers must be more precise so that bonding structures on the further wafer match the bonding areas 35. In the embodiments shown, the wafers are round shaped. However, other shapes of wafers are possible as well. For example, the wafer may have rectangular, such as a quadratic or more generally a polygonal shape.

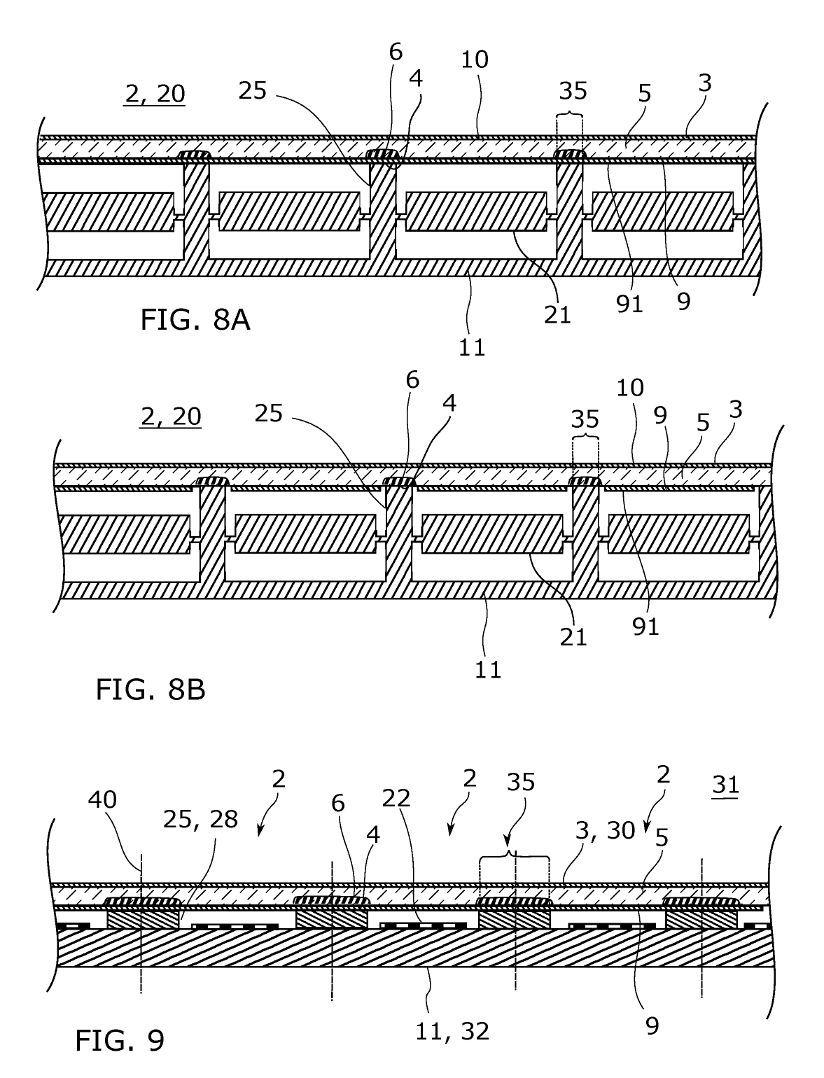

FIGS. 8A and 8B illustrate two examples of components 2 with a coated optical element 1. A component 2 provided according to the invention is illustrated in FIG. 8A and a component 2 that is conventionally produced is illustrated in FIG. 8B as a comparative example. Both embodiments are fabricated by bonding a substrate 3 of alkali containing glass 5 to a further substrate 11. The components of FIGS. 8A and 8B are MOEMS devices.

Specifically, the fabrication comprises the steps of:

providing an optically transparent substrate 3 of an alkali containing glass 5,

depositing a coating 9 on a surface of the substrate 3,

bringing a second substrate 11 into contact with the coating 9 on the optically transparent substrate 3,

heating the optically transparent substrate 3 up to a temperature that enables diffusion of alkali ions in the glass 5, and

applying a voltage across the stack of the optically transparent substrate 3 and the second substrate 11 so that the optically transparent substrate 3 and the second substrate 11 are bonded together.

In the example illustrated in FIG. 8B, the coating 9 has been removed in the bonding areas 35 so that the glass 5 is in direct contact with the second substrate 11.

According to the invention, however, the coating spans over the one or more bonding areas 35. Thus, the second substrate 11 is brought into contact with the coating 9 instead of the glass. When the voltage is applied, alkali ions move away from the interface of the glass 5 and the coating 9 under the influence of the electrostatic field exerted by the applied voltage. This way, an alkali depletion zone 6 in the glass at the interface to the coating is produced, generating a high electrostatic force at the interface, and the optically transparent substrate 3 and the second substrate 11 are bonded together. Akin to the conventional fabrication, thus, an anodic bond 4 is established, however, with the alkali-depletion if formed during the bonding process at the interface from the glass 5 to the coating 9 rather than directly at the anodic bond interface 4. The anodic bond 4 also has comparable strength. A bond strength of more than 7 MPa may be established and the bond strength may even exceed 10 MPa.

The substrate 3 may further be provided with a coating 10 on the opposite face. The coatings 9, 10 may be the same or may be different, e.g. with the coating 9 having an additional layer of a bonding material as in the embodiments of FIG. 3, FIG. 4 and FIG. 5.

The MOEMS device 20 generally comprises one or more optically active or passive elements, such as light sensors, light sources or one or more actuable optomechanical elements 21. These elements interact with light transmitted through the optical element 1. For example, according to some embodiments of the invention and without restriction to the specific embodiment of FIG. 8A, the second substrate of component 2 comprises optomechanical elements 21 in the form of mirrors which are tiltable by an applied voltage or current.

The light transmitted through the optical element 1 and influenced by the optomechanical element 21 may be reflected back through the optical element 1, transmitted through the second substrate 11 or absorbed within the component 2. Generally, the light may be reflected, refracted or generally redirected or emitted by the optically active or passive element in the MOEMS device 20.

Generally and without restriction to the depicted embodiments, the optical element 1 of the component 2 may be a window with a substrate 3 having two opposite plane parallel faces. The window may serve to encapsulate optomechanical or optoelectronic elements, e.g. optoelectronic light sources, sensors and actuators.

As also shown in the exemplary embodiment of FIG. 8A, the second substrate 11 may comprise bonding protrusions onto which the optically transparent substrate 3 is attached. The bonding protrusions 25 may be ridge-like supports. The bonding protrusion 25 may also be a bonding frame which surrounds and encloses the optoelectronic or optomechanic elements of the component 2. Generally, a bonding protrusion may be integrated with the body of the second substrate or may be an additional structure thereon. For example, the second substrate may be a silicon substrate etched or structured such that ridges remain standing around the optoelectronic or optomechanical elements. The bonding protrusion 25 may also be metal structures, such as protrusions produced from an iron-nickel alloy such as Kovar. This metal has a thermal linear expansion coefficient close to silicon. Generally, the second substrate 11 may as well be provided with a coating on the side that is bonded to the transparent substrate 3. As well, it is advantageous to choose a glass 5 with a similar thermal expansion coefficient.

The procedure of the anodic bonding may be performed on wafer level. This means that a glass wafer and a second wafer are joined together and the components to be fabricated are separated from the wafer package at a given time after anodic bonding. This is advantageous, as a structuring as shown in FIG. 7B and a subsequent alignment to bonding protrusions can be omitted. FIG. 9 shows an exemplary embodiment of a wafer package 31 provided according to the invention. The wafer package 31 generally includes an optically transparent wafer 30 and a second wafer 32 with a multitude of optoelectronic or optomechanical elements. The side of the optically transparent wafer 30 facing the second wafer is covered with a coating 9 and the optically transparent wafer 30 and the second wafer are bonded together at bonding areas 35 with anodic bonds 4. The coating 9 extends across the bonding areas 35 so that the coating 9 contacts the second wafer 32 and the anodic bonds are formed between the coating and the second wafer 32. The bonding areas 35 are formed so that components 2 provided according to the invention can be separated from the wafer package 31 along separation lines 40. Thus, the optically transparent substrate 3 and the second substrate 11 of a component 2 are formed from sections of the first and second wafers 30, 32, respectively.

In some embodiments, the bonding areas 35 are defined by bonding protrusions 25, as in the exemplary embodiment of FIG. 8A. The bonding protrusions 25 may be shapes as bonding frames 28 which encircle the devices on the second wafer, e.g. optomechanic or optoelectronic elements 22. This way, the elements are encapsulated after the wafers 30, 32 are joined and bonded together.

In the following, an example for the fabrication of an optical component 2 according to the invention is described. The substrate 3 is a MEMpax-wafer. MEMpax is a borosilicate glass with a linear thermal expansion coefficient α(20° C.; 300° C.)=3.3×10⁻⁶K⁻¹, which is very closely matched to that of Silicon.

An antireflection coating was deposited on the MEMpax wafer. The coating 9 is a 4-layer coating optimized for a wavelength of 905 nm (typical for a NIR laser application). The 4 layers were: 231 nm Ta₂O₅ (lowest layer)/95 nm SiO₂/178 nm Ta₂O₅/125 nm SiO₂ (topmost layer). The outer surface 91 of the coating 9, i.e. the surface of the SiO₂-layer with a thickness of 125 nm has a roughness of 1 to 1.5 nm RMS. This wafer was bonded to a silicon wafer with the coating directly contacting the silicon wafer.

For bonding, an electrostatic voltage of 1250 V was applied and the ion migration, and hence electrostatic force required to initiate the bonding started, as observed from the ion current, at 360 degrees C. The temperature was further increased to 380 degrees C., and the applied voltage and temperature was maintained for 10 to 15 minutes after the onset of ion current was observed. These are typical process parameters for anodic bonding. Longer bond time, higher temperature or other optimizations of the bonding process parameters can result in a larger bonded area and/or a higher bond energy.

It should be appreciated that the invention is not restricted to the specific embodiments as shown in the figures. Rather, the embodiments can be varied within the scope of the claims and the features of different examples may be combined. Inter alia, the invention is not restricted to MEMS- or MOEMS-devices as disclosed in FIG. 8A. Rather, the invention can be generally applied for electronic packaging, with potential applications being hermetic packaging for LED and OLED and laser light sources, Optical, NIR and MIR sensor packaging, where the optically transparent element requiring coating is typically a glass component (not necessarily a wafer) and the packaging it is bonded to may be a metal casing.

While this invention has been described with respect to at least one embodiment, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

### LIST OF REFERENCE SIGNS

| | |
|---|---|
| 1 | optical element |
| 2 | component |
| 3 | transparent substrate |
| 4 | anodic bond |
| 5 | alkali containing glass |
| 6 | alkali depletion zone |
| 7 | surface of substrate 3 |
| 9, 10 | coating |
| 11 | second substrate |
| 13, 15 | faces of 3 |
| 17 | interface between 3, 9 |
| 20 | MOEMS-device |
| 21 | optomechanical element |
| 22 | optoelectronic element |
| 25 | bonding protrusion |
| 26 | transparent wafer |
| 27 | device wafer |
| 28 | bond frame |
| 30 | wafer |
| 31 | wafer package |
| 32 | second wafer |
| 33 | coating exclusion zone |
| 35 | bonding area |
| 40 | separation line |
| 91 | outer surface of 9 |
| 92, 93, 94 | layers of coating 9 |
| 95 | layer of a bondable material |
| 96, 97 | layer of a non-bondable material |

What is claimed is:

1. An optical element, comprising:
an optically transparent substrate of alkali containing glass; and
a coating on a surface of the substrate, the coating enabling anodic bonding of the alkali containing glass within an area of the surface that is covered with the coating and with the anodic bond forming at an outer surface of the coating.

2. The optical element of claim 1, wherein the coating is alkali-free at least at its outer surface.

3. The optical element of claim 1, wherein the outer surface of the coating is hydrophilic or polar.

4. The optical element of claim 1, wherein the outer surface of the coating comprises:
SiO₂, SiOₓ, Al₂O₃, or AlOₓ;
a metal;
a metal oxide;
a fluoride;
a sulfide; or
mixtures thereof.

5. The optical element of claim 1, wherein the substrate has a face that is fully covered by the coating.

6. The optical element of claim 1, wherein a thickness of the coating is in the range of from 2 nm to 50 μm.

7. The optical element according to claim 1, wherein the coating comprises at least two layers.

8. The optical element of claim 7, wherein the at least two layers comprises a layer of a non-bonding material that does not bond to other surfaces by anodic bonding and a further layer of a material that enables anodic bonding of the alkali containing glass on the area of the surface that is covered with the coating.

9. The optical element of claim 8, wherein the further layer has a thickness of between 1 nm and 20 nm.

10. The optical element of claim 7, wherein a thickness of a topmost layer of the coating is in the range of from 50 nm to 1000 nm.

11. The optical element of claim 1, wherein a roughness (Rq) of the outer surface of the coating is between 0.1 and 2 nm RMS.

12. The optical element of claim 1, wherein the coating is:
an anti-reflection coating;
a mirrors coating with or without at least one protection layer; or
a filter coating.

13. The optical element of claim 1, wherein the coating comprises a nitride, an oxynitride, a carbonitride, a carbide, or a mixture thereof.

14. A component, comprising:
an optical element with an optically transparent substrate of alkali containing glass;
a coating on a surface of the substrate; and
a second substrate connected to the optically transparent substrate, the second substrate being connected to the optically transparent substrate by an anodic bond at an area of the surface covered with the coating so that the coating is arranged between the optically transparent substrate and the second substrate and is in direct contact with both the optically transparent substrate and the second substrate.

15. The component of claim 14, wherein the second substrate comprises a silicon part, a silicon oxide covered silicon part, or a metal part that is bonded to the optical element.

16. The component of claim 14, wherein the component is a MEMS-device.

17. The component of claim 14, wherein the glass of the substrate has an alkali depletion zone at an interface to the coating.

18. The component of claim 14, wherein the optical element is a window with a substrate having two opposite plane parallel faces.

19. The component of claim 14, wherein a bond strength of the anodic bond between the coating and the second substrate exceeds 7 MPa.

20. The component of claim 14, wherein the coating has at least one of the following properties:
a material of the coating is not capable of being anodically bonded;
the coating itself does not contain alkali ions in sufficient amount to establish a charge depletion zone at an interface of the anodic bond; or
an alkali content of the coating in mol-% is less than 1/10th of an alkali content of the alkali containing glass.

21. A wafer package, comprising:
an optically transparent wafer;
a second wafer with a plurality of optoelectronic or optomechanical elements; and
a coating covering a side of the optically transparent wafer facing the second wafer, the optically transparent wafer and the second wafer being bonded together at bonding areas with anodic bonding, the coating extending across the bonding areas so that the coating contacts the second wafer and the anodic bonds are formed between the coating and the second wafer.

22. A method for fabricating a component with an optical element, the method comprising:
providing an optically transparent substrate of an alkali containing glass;
depositing a coating on a surface of the substrate, the coating enabling anodic bonding of the alkali containing glass on an area of the surface that is covered with the coating;
bringing a second substrate into contact with the coating on the optically transparent substrate;
heating the optically transparent substrate up to a temperature that enables diffusion of alkali ions in the glass; and
applying a voltage across a stack of the optically transparent substrate and the second substrate so that alkali ions migrate within the bulk of the glass creating an alkali depletion zone and the optically transparent substrate with coating under the influence of the electrostatic field generated by the applied voltage and ion depletion zone at an interface and the second substrate are bonded together.

23. The method of claim 22, wherein:
a stack of the substrate and the coated glass is heated to a temperature above 250° C. but below a glass transition temperature Tg of the glass;
the voltage applied to generate the electric field is above 250V; and
a bond strength is achieved surpassing a fracture strength of the glass of the transparent substrate.
